(19) United States
(12) Patent Application Publication
(10) Pub. No.: US 2014/0026953 A1
(43) Pub. Date: Jan. 30, 2014

(54) Electroconductive Paste Compositions and Solar Cell Electrodes and Contacts Made Therefrom

(71) Applicants: Weiming Zhang, Blue Bell, PA (US); Jerome Moyer, Montclair, NJ (US); Tung T. Pham, Goleta, CA (US)

(72) Inventors: Weiming Zhang, Blue Bell, PA (US); Jerome Moyer, Montclair, NJ (US); Tung T. Pham, Goleta, CA (US)

(73) Assignee: Heraeus Precious Metals North America Conshohocken LLC, West Conshohocken, PA (US)

(21) Appl. No.: 13/980,459

(22) PCT Filed: Jan. 17, 2012
(86) PCT No.: PCT/US2012/021544

§ 371 Date: Oct. 16, 2013

Related U.S. Application Data
(60) Provisional application No. 61/433,706, filed on Jan. 18, 2011.

(51) Int. Cl. H01B 1/16; H01L 31/0224

(52) U.S. Cl. CPC H01B 1/16; H01L 31/022425
USPC 136/256; 252/514

(57) ABSTRACT

Electroconductive paste compositions, particularly for solar cells, contain electroconductive metal particles, glass particles, and an organic vehicle. The electroconductive metal particles are provided as a mixture of silver powder particles and at least one selected from nickel powder, tin (IV) oxide powder, and core-shell particles having a silver shell and a core of nickel and/or tin (IV) oxide. The pastes may be used in the manufacture of contacts or electrodes for the front side or back side of solar cells.

### CROSS-REFERENCE TO RELATED APPLICATIONS

This application claims priority to U.S. Provisional Patent Application No. 61/433,706, filed Jan. 18, 2011, the disclosure of which is herein incorporated by reference in its entirety.

### BACKGROUND OF THE INVENTION

Solar cells are devices that convert the sun's energy into electricity using the photovoltaic effect. Solar power is an attractive energy source because it is sustainable and non-polluting. Accordingly, a great deal of research is currently being devoted to developing solar cells with enhanced efficiency while maintaining low material and manufacturing costs. Very simply, when photons in sunlight hit a solar panel, they are absorbed by semiconducting materials, such as silicon. Electrons are knocked loose from their atoms, allowing them to flow through electroconductive parts of the solar panel and produce electricity.

The most common solar cells are those based on silicon, more particularly, a p-n junction made from silicon by applying an n-type diffusion layer onto a p-type silicon substrate, coupled with two electrical contact layers or electrodes. In order to minimize reflection of the sunlight by the solar cell, an antireflection coating, such as silicon nitride, is applied to the n-type diffusion layer to increase the amount of light coupled into the solar cell. Using a silver paste, for example, a grid-like metal contact may be screen printed onto the antireflection layer to serve as a front electrode. This electrical contact layer on the face or front of the cell, where light enters, is typically present in a grid pattern made of “finger lines” and “bus bars” rather than a complete layer because the metal grid materials are not transparent to light. Finally, a rear contact is applied to the substrate, such as by applying a backside silver or silver/aluminum paste followed by an aluminum paste to the entire backside of the substrate. The device is then fired at a high temperature to convert the metal pastes to metal electrodes. A description of a typical solar cell and the fabrication method thereof may be found, for example, in European Patent Application Publication No. 1 713 093.

A typical silver paste comprises silver particles, glass frit (glass particles), and an organic vehicle. A metal oxide additive, such as zirconium oxide or tin oxide, to enhance binding of the composition to the solar cell, may also be included. These components must be carefully selected to take full advantage of the potential of the resulting solar cell. For example, it is necessary to maximize the contact between the silver particles and the Si surface so that the charge carriers can flow into the finger lines and along the bus bars. If the resistance is too high, the charge carriers are blocked. Thus, minimizing contact resistance is desired. Additionally, the glass particles in the composition etch through the antireflection coating layer, resulting in contact between the Ag particles and the Si surface. However, the glass must not be so aggressive that it penetrates the p-n junction. Known compositions have high contact resistance due to the insulating effect of the glass in the interface of silver layer and Si wafer, and other disadvantages such as high recombination in the contact area. The bulk silver provides a conductive pathway for the charge carriers once they have traversed the glass interface. Electroconductive materials other than silver are of interest as they provide an opportunity to reduce the cost of the silver paste.

### BRIEF SUMMARY OF THE INVENTION

An electroconductive paste composition according to the invention comprises:

(a) electroconductive metal particles;
(b) glass frit; and
(c) an organic vehicle;
wherein the electroconductive metal particles comprise a mixture of silver powder and at least one selected from the group consisting of nickel powder, tin (IV) oxide powder, and core-shell particles comprising a silver shell and a core of nickel and/or tin (IV) oxide.

A solar cell electrode or contact according to the invention is formed by applying the electroconductive paste composition to a substrate and firing the paste to form the electrode or contact.

### DETAILED DESCRIPTION OF THE INVENTION

The electroconductive paste compositions according to the invention comprise three essential components: electroconductive metal particles, glass frit, and an organic vehicle. While not limited to such an application, such pastes may be used to form an electrical contact layer or electrode in a solar cell. Specifically, the pastes may be applied to the front side of a solar cell or to the back side of a solar cell.

Each component in the electroconductive paste compositions will now be described in more detail.

### Electroconductive Metal Particles

The electroconductive metal particles function as an electroconductive metal in the electroconductive paste compositions. The electroconductive particles are preferably present in the composition in an amount of about 40 to about 95% by weight based on the total weight of the composition. For back or rear side pastes, a preferred range of electroconductive particles is about 40 to about 70% by weight, whereas for front side pastes, a preferred range of electroconductive particles is about 60 to about 95%.

### Electroconductive Particles Containing Mixture of Silver Powder and Second Metal Powder

The electroconductive particles may contain a mixture of silver powder and at least one second metal powder preferably selected from nickel powder, copper powder, and metal oxide powder. The second metal powder are preferably present in the mixture in an amount of about 0.1% to about 50% by weight based on the total weight of the mixture. Appropriate metal oxide powders include, without limitation, SiO₂, Al₂O₃, CeO₂, TiO₂, ZnO, In₂O₃, ITO, ZrO₂, GeO₂, CO₃O₄, La₂O₃, TeO₂, Bi₂O₃, PbO, BaO, CaO, MgO, SnO₂ SrO, V₂O₅, MoO₃, Ag₂O, Ga₂O₃, Sb₂O₃, CuO, NiO, Cr₂O₃, Fe₂O₃, and CoO. Preferred second metal powders include nickel and tin (IV) oxide (SnO₂). The silver powder and second metal powder(s) may be combined by any appropriate method known in the art, such as by milling or mixing using 3-roll mills and planetary mixers.

In preferred embodiments, the ratio of silver powder to second metal powder is determined by the use of the silver paste compositions in the solar cell. Specifically, silver pastes may be used for forming the front side (FS) or the back side (BS) of the solar cell. FS silver pastes are applied as grid-like metal contact layers to serve as front electrodes. BS silver pastes are applied to the back side of a solar cell, followed by an aluminum paste to serve as a rear contact. Preferably, the electroconductive particles in FS silver pastes contain about 75% silver powder and about 25% second metal powder. In contrast, in BS silver pastes, the amount of second metal powder in the electroconductive particles may be increased to as high as about 50%. Two properties are important for evaluating silver pastes: electrical conductivity and adhesion to the substrate. The greater possible concentration of second metal powder in the BS pastes is allowed due to the different property requirements of the two types of pastes.

The second metal powders preferably have a particle diameter of about 0.2 to about 20 microns, more preferably about 0.2 to about 10 microns. Unless otherwise indicated herein, all particle sizes stated herein are d₅₀ particle diameters measured by laser diffraction. As well understood by those in the art, the d₅₀ diameter represents the size at which half of the individual particles (by weight) are smaller than the specified diameter.

The silver powder component (which may be also utilized in flake form) preferably has a particle diameter of about 0.3 to about 10 microns. Such diameters provide the silver with suitable sintering behavior and spreading of the electroconductive pastes on the antireflection layer when forming a solar cell, as well as appropriate contact formation and conductivity of the resulting solar cell. It is also within the scope of the invention to utilize other electroconductive metals in place of or in addition to silver, such as copper, as well as mixtures containing silver, copper, gold, palladium, and/or platinum. Alternatively, alloys of these metals may also be utilized as the electroconductive metal.

### Electroconductive Particles Containing Mixture of Silver Powder and Core-Shell Particles

The electroconductive particles may also contain a mixture of silver powder and core-shell particles having a silver shell and a core comprising at least one second metal, such as nickel, copper, or a metal oxide. Appropriate metal oxides include, without limitation, SiO₂, Al₂O₃, CeO₂, TiO₂, ZnO, In₂O₃, ITO, ZrO₂, GeO₂, Co₃O₄, La₂O₃, TeO₂, Bi₂O₃, PbO, BaO, CaO, MgO, SnO₂ SrO, V₂O₅, MoO₃, Ag₂O, Ga₂O₃, Sb₂O₃, CuO, NiO, Cr₂O₃, Fe₂O₃, and CoO. Preferred core metals include nickel and tin (IV) oxide (SnO₂). Preferably, the silver shell comprises about 50 to about 95% by weight of the core-shell particle, and the core, such as nickel and/or SnO₂, comprises about 5% to about 50% by weight. Preferred core-shell particles include particles containing about 90% silver and about 10% nickel and particles containing about 90% silver and about 10% SnO₂, more preferably about 92% silver and about 8% SnO₂. Such core-shell powders are commercially available from Ames Goldsmith Corp and other metal powder manufacturers, and preferably have a particle diameter of about 0.2 to about 20 microns, more preferably about 0.2 to about 10 microns.

The silver powder component of the mixture (which may be also utilized in flake form) preferably has a particle diameter of about 0.3 to about 10 microns. Such diameters provide the silver with suitable sintering behavior and spreading of the electroconductive pastes on the antireflection layer when forming a solar cell, as well as appropriate contact formation and conductivity of the resulting solar cell. It is also within the scope of the invention to utilize other electroconductive metals in place of or in addition to silver, such as copper, as well as mixtures containing silver, copper, gold, palladium, and/or platinum. Alternatively, alloys of these metals may also be utilized as the electroconductive metal.

The silver powder and the core-shell particles are preferably present in a ratio of about 95:5 to about 5:95 based on the total weight of the mixture. The silver and core-shell powders may be combined by any appropriate method known in the art, such as by milling or mixing using 3-roll mills and planetary mixers. In preferred embodiments, the ratio of silver powder to core-shell particles is determined by the use of the silver paste compositions in the solar cell. Preferably, the electroconductive particles in FS silver pastes contain about 75% silver powder and about 25% core/shell particles. In contrast, in BS silver pastes, the amount of core/shell particles in the electroconductive particle mixture may be increased to as high as about 50%. Two properties are important for evaluating silver pastes: electrical conductivity and adhesion to the substrate. The greater possible concentration of core/shell particles in the BS pastes is allowed due to the different property requirements of the two types of pastes.

It is also within the scope of the invention to utilize electroconductive particles containing silver powder combined with both second metal powder(s) (such as nickel and/or tin (IV) oxide), and core-shell particles (such as those comprising a silver shell and a core comprising nickel and/or tin (IV) oxide). Such particles would thus be a mixture of at least three components: silver powder, second metal powder(s), and core-shell particles.

### Glass Frit

The glass frit (glass particles) functions as an inorganic binder in the electroconductive paste compositions and acts as a transport media to deposit silver onto the substrate during firing. The glass system is important for controlling the size and depth of the silver deposited onto the substrate. The specific type of glass is not critical provided that it can give the desired properties to the paste compositions. Preferred glasses include lead borosilicate and bismuth borosilicate, but other lead-free glasses, such as zinc borosilicate, would also be appropriate. The glass particles preferably have a particle size of about 0.1 to about 10 microns, more preferably less than about 5 microns, and are preferably contained in the compositions in an amount of about 0.5 to about 6 weight %, more preferably less than about 5 weight % based on the total weight of the paste composition. Such amounts provide the compositions with appropriate adhesive strength and sintering properties.

### Organic Vehicle

The particular organic vehicle or binder is not critical and may be one known in the art or to be developed for this type of application. For example, a preferred organic vehicle contains a cellulose resin and a solvent, such as ethylcellulose in a solvent such as terpineol. The organic vehicle is preferably present in the electroconductive paste compositions in an amount of about 5 to about 35% by weight based on the total weight of the compositions. More preferably, front side pastes contain about 5 to about 20% organic vehicle and back side pastes contain about 15 to about 35% by weight of the organic vehicle.

It is also within the scope of the invention to include additives in the electroconductive paste compositions. For example, it may be desirable to include thickener (tackifier), stabilizer, dispersant, viscosity adjuster, etc. compounds, alone or in combination. Such components are well known in the art. The amounts of such components, if included, may be determined by routine experimentation depending on the properties of the electroconductive paste that are desired.

The electroconductive paste compositions may be prepared by any method for preparing a paste composition known in the art or to be developed; the method of preparation is not critical. For example, the paste components may be mixed, such as with a mixer, then passed through a three roll mill, for example, to make a dispersed uniform paste.

Such pastes may then be utilized to form contacts and electrodes on a solar cell. A front side paste may be applied to the antireflection layer on a substrate, such as by screen printing, and then fired to form an electrode (electrical contact) on the silicon substrate. A back side paste may be applied to the back side of a substrate, such as by screen printing, followed by application of an aluminum paste, and then firing. Such a method of fabrication is well known in the art and described in EP 1 713 093, for example.

Embodiments of the invention will now be described in conjunction with the following, non-limiting examples.

### Example 1

### Variation in Additive Level in Front Side Pastes

Six electroconductive pastes were prepared by combining the components (silver powder, glass, additives, and organics) of a commercially available silver electroconductive paste, SOL952, from Heraeus Materials Technology LLC (W. Conshohocken, Pa.). In each paste, some of the pure silver powder was replaced with a mixture of silver and a second metal additive. Pastes A, C, and E contained a mixture of SnO₂ powder and silver powder and Pastes B, D, and F contained a mixture of nickel powder and silver powder. The Ag/Ni powder mixture contained 10% Ni and 90% Ag by weight and had a tap density of 1.5 g/cm³, a surface area of 1.6 m²/g, and a D₅₀ of 0.3 microns. The Ag/SnO₂ powder contained 8% SnO₂ and 92% Ag by weight and had a tap density of 1.6 g/cm³, a surface area of 0.8 m²/g, and a D₅₀ of 0.3 microns. The mixture particles were commercially obtained from Ames Goldsmith Corp (South Glen Falls, N.Y.). Pastes A-F contained different amounts of silver/additive mixture: 8% (Pastes A and B), 16% (Pastes C and D), 25% (Pastes E and F), all amounts being based on the total weight percentage of the resulting paste.

Six types of solar cells were prepared as follows: On the backside of a ready-to-be metalized P-type multi-crystalline (mc) silicon wafer, an aluminum paste (RuXing 8252×) was printed and dried at 150° C. A silver paste selected from Pastes A-F was applied to the front side of the wafer, printed, and dried at 150° C. The cells were then co-fired in a furnace, reaching a maximum temperature of 750-800° C. for a few seconds. Four solar cells were prepared using each of Pastes A-F. An additional type of solar cell was prepared as a control using the commercially available silver paste SOL952 (containing no core/shell particles).

The resulting solar cells were tested using an I-V tester. The Xe arc lamp in the I-V tester was used to simulate sunlight with a known intensity and the front surface of the solar cell was irradiated to generate the 1-V curve. Using this curve, various parameters common to this measurement method which provide for electrical performance comparison were determined, including short circuit current (Isc), open circuit voltage (Voc), fill factor (FF), shunt resistance (Rsh), series resistance (Rs), and energy conversion efficiency (Eff).

The electrical performance data for the cells prepared using Pastes A-F, as well as the comparative cell, are tabulated in Table 1 below. Each value in the Table represents the average of four sets of data. It can be seen that both nickel and SnO₂ have lower electrical conductivity than silver, but only a controlled amount of second metal powder can be included in the composition to ensure that the electrical performance is comparable to the composition containing pure silver.

### Example 2

### Variation in Core/Shell Additive Level in Back Side Pastes

Four electroconductive pastes were prepared by combining the components (silver powder, glass, additives, and organics) of a commercially available silver electroconductive paste, CL80-9418, from Heraeus Materials Technology LLC (W. Conshohocken, Pa.). In each paste, some of the pure silver powder was replaced with metal-core coated silver commercially available from Ames Goldsmith Corp (South Glen Falls, N.Y.). Two powders (M and N2) contained silver-coated Ni, and two powders (P and R2) contained silver-coated SnO₂. The Ag-coated Ni powder contained 10% Ni and 90% Ag by weight and had a tap density of 1.5 g/cm³, a surface area of 1.6 m²/g, and a D₅₀ of 1.4 microns. The Ag coated SnO₂ powder contained 8% SnO₂ and 92% Ag by weight and had a tap density of 1.6 g/cm³, a surface area of 0.8 m²/g, and a D₅₀ of 2.6 microns. In powders M and P, a sufficient amount of the commercially available powder was replaced with the core-shell particles so that 50% of the silver in the resulting powder was derived from the core-shell particles. In powders N2 and R2, a sufficient amount of the commercially available powder was replaced with the core-shell particles so that 33% of the silver in the resulting powder was derived from the core-shell particles.

The pastes were applied to the back-side of ready-to-be metalized P-type multi-crystalline (mc) silicon wafers, followed by application of an aluminum paste (RuXing 8252×), and dried at 150° C. Silver paste 9235HL, commercially available from Heraeus Materials Technology LLC (W. Conshohocken, Pa.) was applied to the front side of the wafer and dried at 150° C. The cells were then co-fired in a furnace, reaching a maximum temperature of 750-800° C. for a few seconds. Four solar cells were prepared using each of Pastes M, N², P, and R2. An additional type of solar cell was prepared as a control using the CL80-9418 silver paste (containing no core/shell particles).

In order to evaluate the adhesion of the cells, solder coated copper wires (2 mm wide, 200 μm thick) were soldered onto the solar cells to produce solder joints. Flux was applied to the joint and the wires were soldered to the solar cells. A soldering iron was used to heat the solder and have it flow onto the silver bus bars. The copper wires were cut to ˜10″ in length so that there was a 4″ lead hanging off one end of the 6″ solar cells. The copper lead wires were attached to a force gauge and the cell was affixed to a stage that moved away from the force gauge at a constant speed. A computer was attached to the force gauge to record instantaneous forces. Adhesion was measured 1 and 7 days after production of the solder joints by pulling the wire at a 180° angle relative to the joint. Multiple data points were collected and the average adhesion data are shown in Table 2.

The electrical performance of the solar cells was also evaluated using an I-V tester. The Xe arc lamp in the I-V tester was used to simulate sunlight with a known intensity and the front surface of the solar cell was irradiated to generate the 1-V curve. Using this curve, various parameters common to this measurement method which provide for electrical performance comparison were determined, including short circuit current (Isc), open circuit voltage (Voc), fill factor (FF), shunt resistance (Rsh), series resistance (Rs), and energy conversion efficiency (Eff).

The electrical performance data for the cells prepared using powders M, N2, P, and R2, as well as the comparative cell, are tabulated in Table 3 below. Each value in the Table represents the average of three sets of data. It can be seen that the electrical results are equivalent for the control and experimental pastes from a statistical point of view. The addition of the SnO₂ and Ni core/shell powders has a negligible impact on the series resistance of the cells. The adhesion results indicate that the SnO₂ and Ni core/shell powders do reduce adhesion. However, these results are influenced more by the surface area and particle size used in this test than from their inherent limit for providing good joint adhesion.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

TABLE 1
Comparison of Different Ag/additive mixture Particles in Front Side Silver Pastes

| Paste | Eff¹ | Isc² | Jsc³ | Voc⁴ | FF⁵ | Rs⁶ | Rs3⁷ | Rsh⁸ | Imp⁹ | Ump¹⁰ |
|---|---|---|---|---|---|---|---|---|---|---|
| Control | 15.90 | 8.173 | 33.58 | 0.615 | 76.98 | 0.00516 | 0.00231 | 44 | 7.52 | 0.514 |
| Sample A | 15.72 | 8.111 | 33.33 | 0.612 | 76.96 | 0.00514 | 0.00222 | 68 | 7.46 | 0.512 |
| 8% Ag/SnO₂ | | | | | | | | | | |
| Sample B | 15.90 | 8.167 | 33.55 | 0.614 | 77.14 | 0.00510 | 0.00221 | 87 | 7.52 | 0.514 |
| 8% Ag/Ni | | | | | | | | | | |
| Sample C | 15.83 | 8.129 | 33.40 | 0.615 | 76.96 | 0.00511 | 0.00217 | 65 | 7.47 | 0.515 |
| 16% Ag/SnO₂ | | | | | | | | | | |
| Sample D | 15.36 | 8.054 | 33.09 | 0.610 | 76.02 | 0.00533 | 0.00224 | 44 | 7.35 | 0.508 |
| 16% Ag/Ni | | | | | | | | | | |
| Sample E | 15.32 | 8.104 | 33.30 | 0.608 | 75.58 | 0.00525 | 0.00211 | 52 | 7.36 | 0.506 |
| 25% Ag/SnO₂ | | | | | | | | | | |
| Sample F | 15.04 | 8.015 | 32.93 | 0.607 | 75.22 | 0.00542 | 0.00222 | 40 | 7.27 | 0.503 |
| 25% Ag/Ni | | | | | | | | | | |

¹Eff: energy conversion efficiency
²Isc: short circuit current
³Jsc: short circuit current density
⁴Voc: open circuit voltage
⁵FF: fill factor
⁶Rs: series resistance
⁷Rs3: series resistance squared
⁸Rsh: shunt resistance
⁹Imp: current at maximum power
¹⁰Ump: voltage at maximum power

TABLE 2
Adhesion of Back Side Pastes

Adhesion (grams force)

| Paste | Day 1 | Day 7 |
|---|---|---|
| Control | 803 | 641 |
| M | 113 | 107 |
| N2 | 183 | 198 |
| P | 313 | 216 |
| R2 | 389 | 304 |

TABLE 3
Comparison of Different Core/Shell Particles in Back Side Silver Pastes

| Paste | Eff¹ | Isc² | Jsc³ | Voc⁴ | FF⁵ | Rs⁶ | Rs3⁷ | Rsh⁸ | Imp⁹ | Ump¹⁰ |
|---|---|---|---|---|---|---|---|---|---|---|
| Control | 15.72 | 7.966 | 32.73 | 0.6144 | 78.2 | 0.00568 | 0.00284 | 135 | 7.45 | 0.513 |
| M (50% Ni—Ag) | 15.51 | 7.939 | 32.62 | 0.6132 | 77.6 | 0.00567 | 0.00267 | 97 | 7.37 | 0.512 |
| N2 (33% Ni—Ag) | 15.54 | 7.952 | 32.67 | 0.6137 | 77.5 | 0.00572 | 0.00308 | 100 | 7.40 | 0.512 |
| P (50% SnO₂—Ag) | 15.71 | 7.945 | 32.65 | 0.6149 | 78.3 | 0.00562 | 0.00288 | 120 | 7.42 | 0.515 |
| R2 (33% SnO₂—Ag) | 15.63 | 7.960 | 32.71 | 0.6140 | 77.8 | 0.00568 | 0.00284 | 113 | 7.43 | 0.512 |

¹Eff: energy conversion efficiency
²Isc: short circuit current
³Jsc: short circuit current density
⁴Voc: open circuit voltage
⁵FF: fill factor
⁶Rs: series resistance
⁷Rs3: series resistance squared
⁸Rsh: shunt resistance
⁹Imp: current at maximum power
¹⁰Ump: voltage at maximum power

We claim:

1. An electroconductive paste composition comprising:
(a) electroconductive metal particles;
(b) glass frit; and
(c) an organic vehicle;
wherein the electroconductive metal particles comprise a mixture of silver powder and at least one selected from the group consisting of nickel powder, tin (IV) oxide powder, and core-shell particles comprising a silver shell and a core of nickel and/or tin (IV) oxide.

2. The composition according to claim 1, comprising about 40 to about 95% electroconductive metal particles, about 0.5 to about 6% glass frit, and about 5 to about 35% organic vehicle, all percentages being by weight based on the total weight of the composition.

3. The composition according to claim 1, wherein the electroconductive metal particles comprise a mixture of silver powder and core-shell particles comprising a silver shell and a core of nickel and/or tin (IV) oxide, and wherein the silver shell comprises about 50 to 95 wt % and the core comprises about 5 to 50 wt %, all percentages being based on the total weight of the core-shell particles.

4. The composition according to claim 3, wherein the core-shell particles comprise about 90 wt % silver shell and about 10 wt % core, all percentages being based on the total weight of the core-shell particles.

5. The composition according to claim 1, wherein the electroconductive metal particles comprise a mixture of silver powder and core-shell particles comprising a silver shell and a core of nickel and/or tin(IV)oxide, and wherein the core-shell particles have a diameter of about 0.2 to about 20 microns.

6. The composition according to claim 1, wherein the electroconductive metal particles comprise a mixture of silver powder and core-shell particles comprising a silver shell and a core of nickel and/or tin(IV)oxide, and wherein a ratio of silver powder to core-shell particles in the mixture is about 95:5 to about 5:95.

7. The composition according to claim 1, wherein the electroconductive metal particles comprise a mixture of silver powder and nickel and/or tin (IV) oxide powder, and wherein the nickel and/or tin (IV) oxide powder comprises about 0.1% to about 50% by weight based on a total weight of the mixture.

8. A solar cell electrode or contact formed by applying the electroconductive paste composition according to claim 1 to a substrate and firing the paste to form the electrode or contact.

9. The solar cell electrode or contact according to claim 8, wherein the paste composition comprises about 40 to about 95% electroconductive metal particles, about 0.5 to about 6% glass frit, and about 5 to about 35% organic vehicle, all percentages being by weight based on the total weight of the composition.

10. The solar cell electrode or contact according to claim 8, wherein the electroconductive metal particles in the paste composition comprise a mixture of silver powder and core-shell particles comprising a silver shell and a core of nickel and/or tin (IV) oxide, and wherein the silver shell comprises about 50 to 95 wt % and the core comprises about 5 to 50 wt %, all percentages being based on the total weight of the core-shell particles.

11. The solar cell electrode or contact according to claim 10, wherein the core-shell particles comprise about 90 wt % silver shell and about 10 wt % core, all percentages being based on the total weight of the core-shell particles.

12. The solar cell electrode or contact according to claim 8, wherein the electroconductive metal particles in the paste composition comprise a mixture of silver powder and core-shell particles comprising a silver shell and a core of nickel and/or tin(IV)oxide, and wherein the core-shell particles have a diameter of about 0.2 to about 20 microns.

13. The solar cell electrode or contact according to claim 8, wherein the electroconductive metal particles in the paste composition comprise a mixture of silver powder and core-shell particles comprising a silver shell and a core of nickel and/or tin (IV) oxide, and wherein a ratio of silver powder to core-shell particles in the mixture is about 95:5 to about 5:95.

14. The solar cell electrode or contact according to claim 8, wherein the electroconductive metal particles in the paste composition comprise a mixture of silver powder and nickel and/or tin (IV) oxide powder, and wherein the nickel and/or tin (1V) oxide powder comprises about 0.1% to about 50% by weight based on a total weight of the mixture.
